(19) United States
(12) Patent Application Publication
(10) Pub. No.: US 2009/0039490 A1
(43) Pub. Date: Feb. 12, 2009

(54) Mounting assembly of semiconductor packages prevent soldering defects caused by substrate warpage

(75) Inventor: Wen-Jeng Fan, Hukou Shiang (TW)

Correspondence Address: Joe McKinney Muncy, PO Box 1364, Fairfax, VA, 22038-1364, US

(73) Assignee: POWERTECH TECHNOLOGY INC.

(21) Appl. No.: 11/889,018

(22) Filed: Aug. 8, 2007

(51) Int. Cl. H01L 23/12

(52) U.S. Cl. 257/686

(57) ABSTRACT

A mounting assembly of semiconductor packages is revealed, primarily comprising at least a semiconductor package having a plurality of external terminals, a package carrier, and solder paste. The solder paste joints the external terminals to the package carrier. According to the distance to a central line on a substrate of the semiconductor package, the external terminals are divided into at least two different groups. In one of the embodiment, different groups of the external terminals are bumps with non-equal heights to achieve a uniform standoff plane to compensate the warpage of the substrate. The predicted substrate warpage can be compensated without causing any soldering defects. In another embodiment, a plurality of compensating bumps are selectively disposed on one group of the external terminals with larger stacking gaps.

### FIELD OF THE INVENTION

The present invention relates to the assembling technologies of semiconductor packages, especially to a mounting assembly of semiconductor packages to prevent soldering defects caused by substrate warpage which can be implemented in 3D packaging of Package-On-Package device (POP).

### BACKGROUND OF THE INVENTION

As the thickness requirements of POP semiconductor packages become thinner and thinner, the warpage of the substrates of semiconductor packages become worse and worse leading to soldering defects such as cold soldering, empty soldering, and fault soldering. Soldering defects become a serious issue, especially in 3D stacking of semiconductor packages (or called POP device). In the miniature development of electronic products, a plurality of semiconductor packages can be vertically stacked to meet the requirements of higher density devices with smaller footprints. However, electrical connections between two electrical terminals of POP stacking will easily be open due to substrate warpage during package stacking, especially for fine pitch applications.

Two known micro contact structures for package stacking had been revealed in U.S. Pat. No. 6,476,503 by Fujitsu and in US patent publication No. 2006/0138647 by Tessera, as shown in FIG. 1. A conventional mounting assembly 100 of semiconductor packages primarily comprises a first semiconductor package 110, a second semiconductor package 120, and solder paste 130 where the first semiconductor package 110 is stacked on top of the second semiconductor package 120. The first semiconductor package 110 is electrically connected with the second semiconductor package 120 by the solder paste 130. The first semiconductor package 110 includes a first substrate 111, a first chip 112 disposed on the top surface 111A of the first substrate 111, and a plurality of bumps 113 disposed on the bottom surface 111B of the substrate 111, where the bumps 113 are copper bumps or other non-reflow collar bumps as micro contacts for package stacking. A plurality of the first bonding wires 114 pass through the first slot 111C of the substrate 111 to electrically connect the bonding pads of the first chip 112 to the first substrate 111, and the first bonding wires 114 are encapsulated by a first encapsulant 115 in the first slot 111C. The second semiconductor package 120 is used as a package carrier. As the same as the first semiconductor package 110, the second semiconductor package 120 includes a second substrate 121, a second chip 122 disposed on the top surface 121A of the second substrate 121, and a plurality of bumps 123 disposed on the bottom surface 121B of the second substrate 121 as external terminals. A plurality of bonding wires 124 pass through the second slot 121C of the second substrate 121 to electrically connect the bonding pads of the second chip 122 to the second substrate 121 where the second bonding wires 124 are encapsulated by a second encapsulant 125 in the second slot 121C.

The second semiconductor package 120 has a plurality of planar connecting pads 121D which are disposed on the top surface 121A of the second substrate 121 and are electrically connected with the corresponding bumps 113 of the first semiconductor package 110 by the solder paste 130 by reflowing to achieve micro contact mechanisms. When the first semiconductor package 110 is stacked on the second semiconductor package 120 by the bumps 113 as micro contacts, signal pin counts and routing area can be increased and the POP stacking standoff can be reduced. However, the acceptable tolerance of the substrate warpage become smaller for such mounting assembly 100. The first substrate 111 will be experienced temperature cycles during package stacking and reflowing of the solder paste 130 leading to substrate warpage and causing random stacking spacing between the bumps 113 and the corresponding connecting pads 121D. Therefore, as shown in FIG. 1 again, some solder paste 130 can not properly solder the bumps 113 and the corresponding connecting pads 121D together due to substrate warpage so as to cause various soldering defects.

### SUMMARY OF THE INVENTION

The main purpose of the present invention is to provide a mounting assembly of semiconductor packages to prevent soldering defects caused by substrate warpage where the POP stacking standoffs for solder paste is reduced and has a larger tolerance to avoid soldering defects caused by substrate warpage.

The second purpose of the present invention is to provide a mounting assembly of semiconductor packages to prevent soldering defects caused by substrate warpage, which possesses good heat dissipation and constant spacing of micro contacts for soldering.

According to the present invention, a mounting assembly of semiconductor packages primarily comprises at least a first semiconductor package, a package carrier, and solder paste. The first semiconductor package includes a first substrate, a first chip, a plurality of first external terminals, and a plurality of second external terminals where the first external terminals and the second external terminals are disposed on a bottom surface of the first substrate. The package carrier has a plurality of first connecting pads and a plurality of second connecting pads on the same surface. Solder paste joints the first external terminals to the first connecting pads and joints the second external terminals to the second connecting pads.

In another embodiment, a mounting assembly of semiconductor packages to prevent soldering defects caused by substrate warpage primarily comprises at least a first semiconductor package, a package carrier, and solder paste. The first semiconductor package includes a first substrate, a first chip, a plurality of first external terminals, and a plurality of second external terminals where the first external terminals and the second external terminals are disposed on the bottom surface of the first substrate. The package carrier has a plurality of first connecting pads and a plurality of second connecting pads on the same surface. Solder paste joints the first external terminals to the first connecting pads and connect the second external terminals to the second connecting pads. The first substrate has a central line defined thereon where the distance between the first external terminals to the center line is smaller than the distance between the second external terminals to the center line. The mounting assembly further comprises a plurality of compensating bumps selectively disposed on either the first connecting pads or the second connecting pads to compensate the warpage of the first substrate when the first semiconductor package is mounted on the package carrier.

### DESCRIPTION OF THE DRAWINGS

FIG. 1 shows a cross-sectional view of a conventional mounting assembly of semiconductor packages.

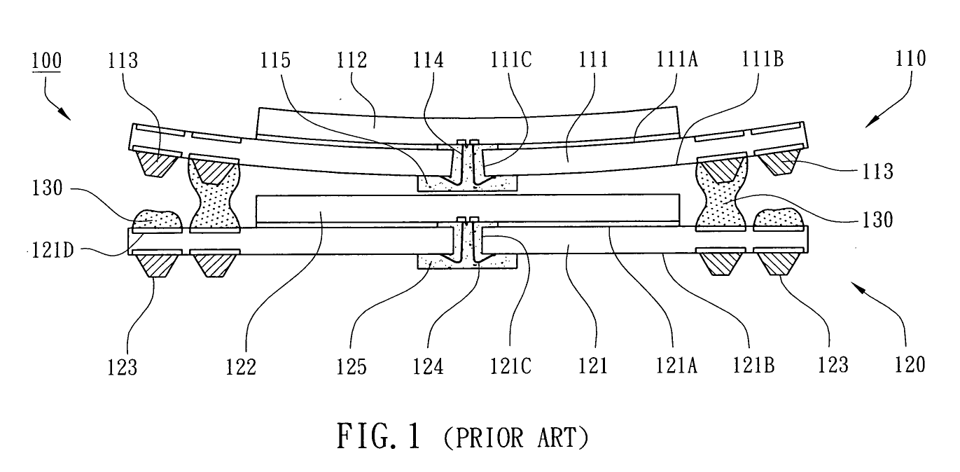

FIG. 2 shows a cross-sectional view of a mounting assembly of semiconductor packages according to the first embodiment of the present invention.

FIG. 3 shows a bottom view of a first semiconductor package from the mounting assembly according to the first embodiment of the present invention.

FIG. 4 shows a cross-sectional view of a mounting assembly of semiconductor packages according to the second embodiment of the present invention.

FIG. 5 shows a cross-sectional view of a mounting assembly of semiconductor packages according to the third embodiment of the present invention.

FIG. 6 shows a cross-sectional view of a mounting assembly of semiconductor packages according to the fourth embodiment of the present invention.

### DETAIL DESCRIPTION OF THE INVENTION

Please refer to the attached drawings, the present invention will be described by means of embodiment(s) below.

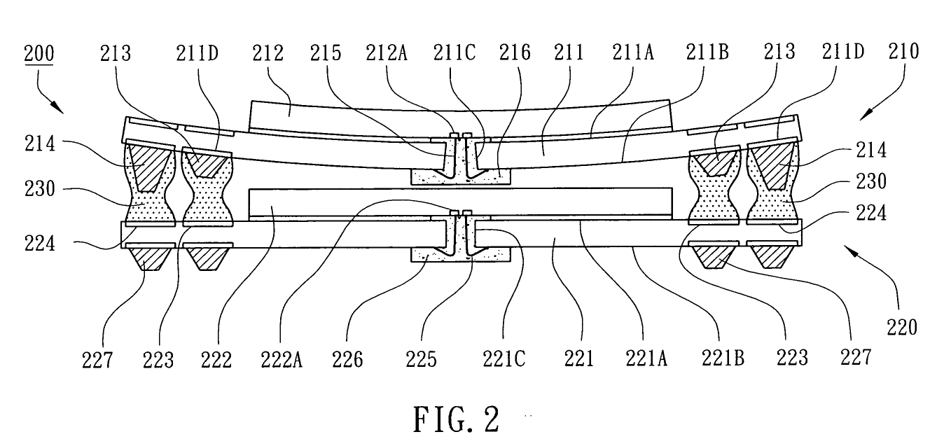

According to the first embodiment of the present invention, as shown in FIG. 2, a mounting assembly 200 of semiconductor packages primarily comprises at least a first semiconductor package 210, a package carrier 220, and solder paste 230 where the first semiconductor package 210 is mounted on top of the package carrier 220 and is electrically connected to the package carrier 220 by solder paste 230.

The first semiconductor package 210 includes a first substrate 211, a first chip 212, a plurality of first external terminals 213, and a plurality of second external terminals 214. The first substrate 211, such as printed circuit boards, acts as an electrically connecting medium of the first chip 212 to the package carrier 220. The first substrate 211 has a top surface 211 A and a bottom surface 211B. The first chip 212 is an IC fabricated on a Si wafer and may be a processor, a memory, a logic, an ASIC, or a multi-functional IC. The first external terminals 213 and the second external terminals 214 are disposed at a plurality of connecting pads 211D on the bottom surface 211B of the substrate 211 where the first external terminals 213 and the second external terminals 214 may include plated pillar bumps or gold stud bumps and made of copper, gold, or other conductive materials. In this embodiment, the first external terminals 213 and the second external terminals 214 have profiles of hemi-pyramids or hemi-cones with trapezoid cross-sections as micro contacts.

To be more specific, the first substrate 211 is a double-layer printed circuit board, i.e., the connecting pads on the top surface 211A are electrically interconnected to the connecting pads 211D on the bottom surface 211B by wiring pattern(s) or/and vias. The active surface of the first chip 212 is disposed on the top surface 211A of the first substrate 211 by die-attach material, tapes, or flip chip bumps. In the present embodiment, the first semiconductor package 210 has window BGA configuration. The first substrate 211 has a first slot 211C penetrating from the top surface 211A to the bottom surface 211B of the first substrate 211 to expose the first bonding pads 212A of the first chip 212. The first semiconductor package 210 further comprises a plurality of first bonding wires 215 passing through the first slot 211C to electrically connect the first bonding pads 212A of the first chip 212 to the inner fingers of the first substrate 211.

The first semiconductor package 210 further comprises a first encapsulant 216 formed in the first slot 211C to encapsulate the first bonding wires 215 by molding or by dispensing. The first chip 212 has a back surface exposed from the first encapsulant 216 for better heat dissipation and for thinner packages. In order to achieve thinner POP stacking, the peripheries of the top surface 211A of the first substrate 211 will not be covered by the first chip 212 nor by the first encapsulant 216. Moreover, since components disposed on the top surface 211A and on the bottom surface 211B of the first substrate 211 are asymmetric, therefore, warpage of the first substrate 211 will occur easily under temperature cycles.

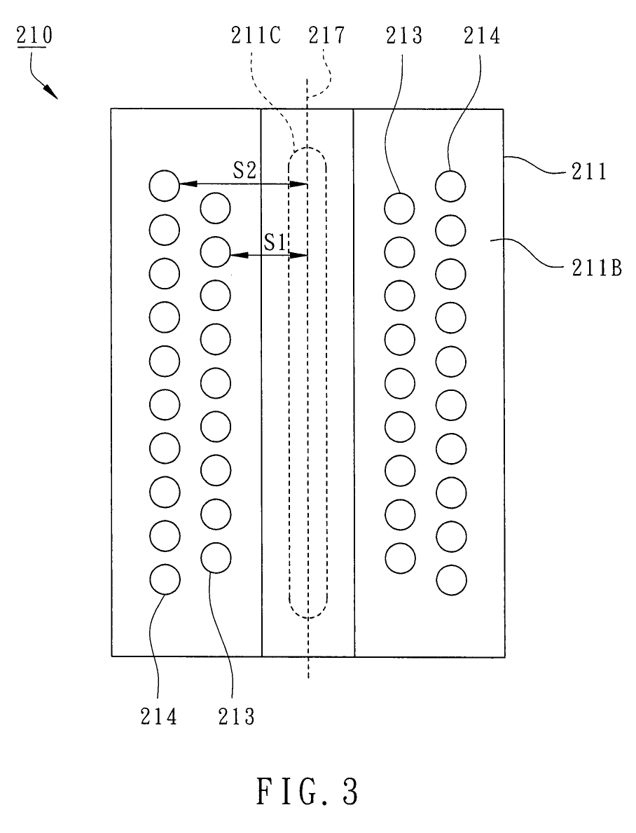

As shown in FIG. 3, the first substrate 211 has a central line 217 defined thereon according to the center bonding pad arrangement of the first chip 212 where the distance S1 from the first external terminals 213 to the central line 217 is smaller than the distance S2 from the second external terminals 214 to the central line 217. The first slot 211C of the first substrate 211 is formed along the central line 217 to expose the first bonding pads 212A of the first chip 212.

As shown in FIG. 2 again, the package carrier 220 has a plurality of first connecting pads 223 and a plurality of second connecting pads 224 on the same surface. In the present embodiment, the first connecting pads 223 and the second connecting pads 224 are planar metal pads. When the first semiconductor package 210 is mounted on the package carrier 220, the first external terminals 213 are aligned to the first connecting pads 223 and the second external terminals 214 aligned to the second connecting pads 224 for soldering. Normally, solder paste 230 is lead-free solder paste such as 96.5% of tin, 3% of silver, and 0.5% of copper with the reflowing temperature about 217° C. At the maximum reflowing temperature of 245° C., the wetting property of soldering will be present. The first external terminals 213 and the second external terminals 214 have melting temperatures higher than the reflowing temperature.

Solder paste 230 joins the first external terminals 213 to the first connecting pads 223 and join the second external terminals 214 to the second connecting pads 224. In the present embodiment, the package carrier 220 is about the same as the first semiconductor package 210 where the package carrier 220 may be a second semiconductor package comprising a second substrate 221, a second chip 222, and a plurality of third external terminals 227 disposed on a bottom surface 221B of the second substrate 221. The first connecting pads 223 and the second connecting pads 224 are disposed on a top surface 221A of the second substrate 221. The second chip 222 is disposed on the top surface 221A of the second substrate 221 without covering the first connecting pads 223 nor the second connecting pads 224.

One of the key technologies of the present invention is that the first external terminals 213 and the second external terminals 214 are bumps with non-equal heights protruding from the bottom surface 211B of the first substrate 211 to compensate the warpage of the first substrate 211 when the first semiconductor package 210 is mounted on the package carrier 220. Accordingly, the POP stacking standoffs between the first external terminals 213 and the first connecting pads 223 and between the second external terminals 214 and the second connecting pads 224 will be approximately the same for good soldering.

As shown in FIG. 2 again, during one of the simulations to predict the warpage of the first substrate 211, when the sides of the first substrate 211 adjacent to the second external terminals are bent upward to warp away from the package carrier 220, the second external terminals 214 have larger bump heights than the ones of the first external terminals 213 so that both the first and the second external terminals 213 and 214 have the same uniform standoff plane. The second external terminals 214 with larger bump heights can compensate the extra stacking standoff differences of the first external terminals 213 without causing soldering open. Moreover, no extra solder paste is needed to dispose between the second external terminals 214 and the second connecting pads 224 to avoid bridging shorts due to the expansion of solder paste 230 during reflow. The acceptable tolerance of stacking standoffs between the first external terminals 213 and the first connecting pads 223 and between the second external terminals 214 and the second connecting pads 224 are enlarged and compensated. Therefore, the solder paste 230 will have effective soldering without open nor short and without soldering defects such as cold soldering, nor empty soldering, nor fault soldering.

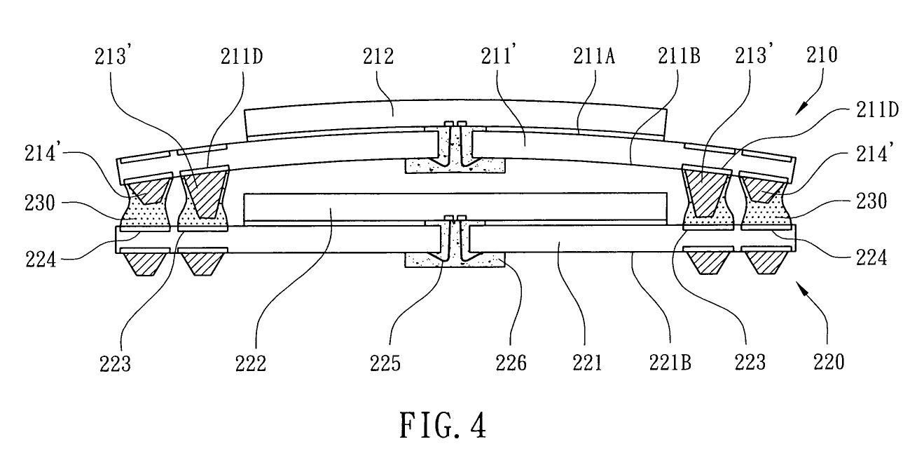

As shown in FIG. 4, another mounting assembly of semiconductor packages is revealed according to the second embodiment of the present invention where the major components are the same as the first embodiment, comprising a first semiconductor package 210, a package carrier 220, and solder paste 230 except the first semiconductor package 210 includes a first substrate 211′, a first external terminals 213′, and a second external terminals 214′, and all the rest of the components are the same as the first embodiment with the same figure numbers. The first external terminals 213′ and the second external terminals 214′ are disposed at the connecting pads 211D on the bottom surface 211B of the first substrate 211. The first chip 212 of the first semiconductor package 210 is disposed on the top surface 211A of the first substrate 211′ and is electrically connected with the first substrate 211′ by a plurality of bonding wires 225.

As shown in FIG. 4 again, during one of the simulations to predict the warpage of the first substrate 211′, when the sides of the first substrate 211′ are bent downward to warp toward the package carrier 220, the first external terminals 213′ have larger bump heights than the ones of the second external terminals 214′ so that both the first and the second external terminals 213′ and 214′ have the same uniform standoff plane. The first external terminals 213′ with larger bump heights can compensate the extra stacking standoff differences of the second external terminals 214′ without causing soldering open. Moreover, no extra solder paste is needed to dispose between the first external terminals 213′ and the first connecting pads 224 to avoid bridging short due to expansion of solder paste 230 during reflow. The acceptable tolerance of stacking standoffs between the first external terminals 213′ and the first connecting pads 223 and between the second external terminals 214′ and the second connecting pads 224 are enlarged and compensated. Therefore, the solder paste 230 will have effective soldering without open nor short and without soldering defects such as cold soldering, nor empty soldering, nor fault soldering.

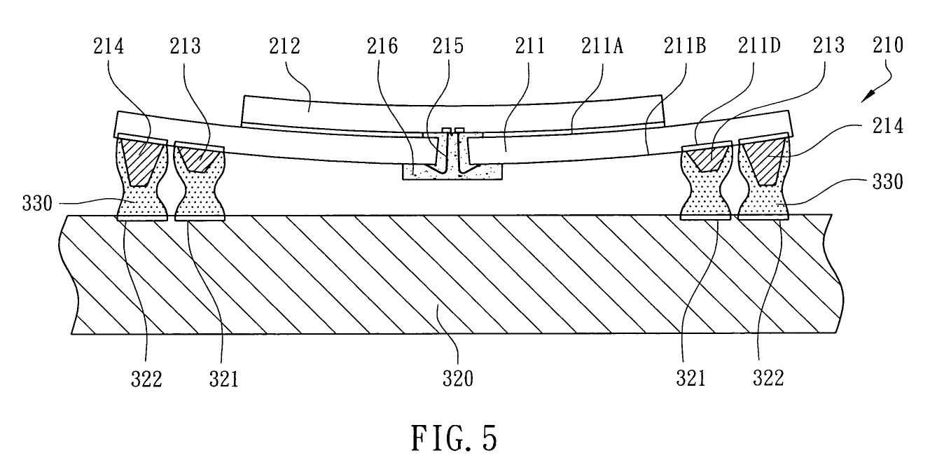

As shown in FIG. 5, another mounting assembly of semiconductor packages is revealed according to the third embodiment of the present invention, comprising at least a semiconductor package 210, a package carrier 320, and solder paste 330 where the semiconductor package 210 is the same as the first semiconductor package 210 mentioned as the first embodiment and marked with the same figure number. The semiconductor package 210 includes a substrate 211, a chip 212, a plurality of first external terminals 213, and a plurality of second external terminals 214 where the first external terminals 213 and the second external terminals 214 are disposed on the bottom surface 211B of the substrate 211. Moreover, the distance from the first external terminals 213 to a central line of the substrate 211 is smaller than the distance from the second external terminals 214 to the central line. The chip 212 is disposed on the top surface 211A of the substrate 211 and is electrically connected to the substrate 211 by the solder paste 330. A plurality of connecting pads 211D are disposed on the bottom surface 21 1B of the substrate 211 for depositing the first external terminals 213 and the second external terminals 214. The chip 212 is partially encapsulated by an encapsulant 216 without encapsulating the sides and the backside of the chip 212 to achieve good heat dissipation and thinner packages.

The package carrier 320 has a plurality of first connecting pads 321 and a plurality of second connecting pads 322 on a same surface where solder paste 330 joints the first external terminals 213 to the first connecting pads 321 and the second external terminals 214 to the second connecting pads 322. In the present embodiment, the package carrier 320 is a printed circuit board such as mother board, memory module board, display board, memory card substrate, or communication board for cellular phones.

The first external terminals 213 and the second external terminals 214 include bumps with non-equal heights protruding from the bottom surface 211B of the first substrate 211 to compensate the warpage of the first substrate 211 when the first semiconductor package 210 is mounted on the package carrier 320. It is to reduce the stacking standoffs between the first external terminals 213 and the first connecting pads 321 and between the second external terminals 214 and the second connecting pads 322. As shown in FIG. 5, when the sides of the substrate 211 adjacent to the second external terminals 214 are bent upward to warp away from the package carrier 320, the second external terminals 214 with larger bump heights can compensate the extra stacking standoff differences compared to the first external terminals 213. In one embodiment, the peripheries of the top surface 211A of the substrate 211 are exposed from the chip 212 and the encapsulant 216, the first and the second external terminals 213 and 214 are disposed within the peripheries of the bottom surface 211B of the substrate 211, not located beneath the chip 212.

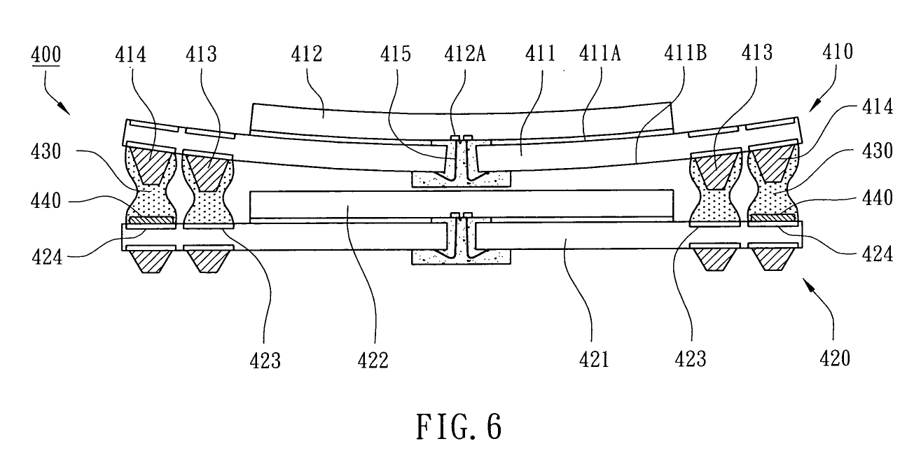

As shown in FIG. 6, another mounting assembly 400 of semiconductor packages is revealed according to the fourth embodiment of the present invention, primarily comprising at least a semiconductor package 410, a package carrier 420, and solder paste 430, and further comprising a plurality of compensating bumps 440 on the package carrier 420.

The first semiconductor package 410 includes a first substrate 411, a first chip 412, a plurality of first external terminals 413, and a plurality of second external terminals 414 where the first external terminals 413 and the second external terminals 414 are disposed on a bottom surface 411B of the first substrate 411. The first chip 412 is disposed on a top surface 411A, but not limited, the first chip 412 may be disposed on the bottom surface 411B of the first substrate 411 or in a die cavity of the first substrate 411 (not shown in figures). The bonding pads 412A of the first chip 412 are electrically connected to the first substrate 411 by a plurality of bonding wires 415.

The package carrier 420 has a plurality of first connecting pads 423 and a plurality of second connecting pads 424 on the same surface. In the present embodiment, the package carrier 420 is a second semiconductor package, including a second substrate 421 and a second chip 422. The second semiconductor package can be the same or not the same as the first semiconductor package 410. The second chip 422 is disposed on the second substrate 421. Solder paste 430 joints the first external terminals 413 to the first connecting pads 423 and the second external terminals 414 to the second connecting pads 424. The first substrate 411 has a central line defined thereon where the distance from the first external terminals 413 to the central line is smaller than the distance from the second external terminals 414 to the central line.

The compensating bumps 440 are selectively disposed either on the first connecting pads 423 or on the second connecting pads 424 to compensate the stacking standoff differences between the second external terminals 414 and the first external terminals 413 when the first semiconductor package 410 is mounted on the package carrier 420. It is to reduce the stacking standoffs between the first external terminals 413 and the first connecting pads 423 and between the second external terminals 414 and the second connecting pads 424 caused by the warpage of the first substrate 411. As shown in FIG. 6 again, when the sides of the first substrate 411 adjacent to the second external terminals 414 are bent upward to warp away from the package carrier 420 due to thermal stresses, the compensating bumps 440 should be disposed on the second connecting pads 424 can compensate the extra stacking standoff differences to resolve the soldering defects due to substrate warpage, especially for micro contacts of high density 3D POP.

The above description of embodiments of this invention is intended to be illustrative and not limiting. Other embodiments of this invention will be obvious to those skilled in the art in view of the above disclosure.

What is claimed is:

1. A mounting assembly of semiconductor package(s), comprising:
at least a first semiconductor package including a first substrate, a first chip, a plurality of first external terminals, and a plurality of second external terminals, wherein the first external terminals and the second external terminals are disposed on a bottom surface of the first substrate;
a package carrier having a plurality of first connecting pads and a plurality of second connecting pads on the same surface; and
solder paste jointing the first external terminals to the first connecting pads and jointing the second external terminals to the second connecting pads;
wherein the first substrate has a central line defined thereon, the distance from the first external terminals to the central line is smaller than the distance from the second external terminals to the central line;
wherein the first external terminals and the second external terminals are bumps with non-equal heights protruding from the bottom surface of the first substrate to compensate the warpage of the first substrate when the first semiconductor package is mounted on the package carrier.

2. The mounting assembly as claimed in claim 1, wherein the first substrate has a plurality of sides adjacent to the second external terminals, which are bent upward to warp away from the package carrier, the second external terminals have larger bump heights than the ones of the first external terminals so that both the first and the second external terminals have the same uniform standoff plane.

3. The mounting assembly as claimed in claim 1, wherein the first substrate have a plurality of sides adjacent to the second external terminals, which are bent downward to warp toward the package carrier, the first external terminals have larger bump heights than the ones of the second external terminals so that both the first and the second external terminals have the same uniform standoff plane.

4. The mounting assembly as claimed in claim 1, wherein the first chip is disposed on a top surface of the first substrate.

5. The mounting assembly as claimed in claim 1, wherein the first substrate has a first slot along the central line to expose a plurality of bonding pads of the first chip.

6. The mounting assembly as claimed in claim 5, wherein the first semiconductor package further includes a plurality of first bonding wires passing through the first slot to electrically connect the bonding pads to the first substrate.

7. The mounting assembly as claimed in claim 6, wherein the first semiconductor package further includes a first encapsulant formed in the first slot to encapsulate the first bonding wires.

8. The mounting assembly as claimed in claim 7, wherein the first chip has a back surface exposed from the first encapsulant.

9. The mounting assembly as claimed in claim 1, wherein the package carrier is a printed circuit board.

10. The mounting assembly as claimed in claim 1, wherein the package carrier is a second semiconductor package, further comprising a second substrate, a second chip, and a plurality of third external terminals, wherein the third external terminals are disposed on the bottom surface of the second substrate, and the first connecting pads and the second connecting pads are disposed on a top surface of the second substrate.

11. The mounting assembly as claimed in claim 10, wherein the second chip is disposed on the top surface of the second substrate without covering the first connecting pads nor the second connecting pads.

12. The mounting assembly as claimed in claim 10, wherein the second semiconductor package is almost the same as the first semiconductor package, comprising a plurality of second bonding wires and a second encapsulant.

13. The mounting assembly as claimed in claim 1, wherein the first external terminals and the second external terminals include plated pillar bumps or gold stud bumps.

14. The mounting assembly as claimed in claim 1, wherein the first external terminals and the second external terminals have profiles of hemi-pyramids or hemi-cones.

15. A mounting assembly of semiconductor packages, comprising:
at least a first semiconductor package including a first substrate, a first chip, a plurality of first external terminals, and a plurality of second external terminals, wherein the first external terminals and the second external terminals are disposed on a bottom surface of the first substrate;
a package carrier having a plurality of first connecting pads and a plurality of second connecting pads on the same surface; and
solder paste jointing the first external terminals to the first connecting pads and jointing the second external terminals to the second connecting pads;
wherein the first substrate has a central line defined thereon, the distance from the first external terminals to the central line is smaller than the distance from the second external terminals to the central line;
further comprising a plurality of compensating bumps selectively disposed either on the first connecting pads or on the second connecting pads to compensate the warpage of the first substrate when the first semiconductor package is mounted on the package carrier.

16. The mounting assembly as claimed in claim 15, wherein the first substrate has a plurality of sides adjacent to the second external terminals, which are bent upward to warp away from the package carrier, the compensating bumps are disposed on the second connecting pads to compensate the stacking standoff differences between the second external terminals and the first external terminals.

17. The mounting assembly as claimed in claim 15, wherein the first substrate have a plurality of sides adjacent to the second external terminals, which are bent downward to warp toward the package carrier, the compensating bumps are disposed on the first connecting pads to compensate the stacking standoff differences between the first external terminals and the second external terminals.

18. The mounting assembly as claimed in claim 15, wherein the first chip is disposed on a top surface of the first substrate.

19. The mounting assembly as claimed in claim 15, wherein the first substrate has a first slot along the central line to expose a plurality of bonding pads of the first chip.

20. The mounting assembly as claimed in claim 19, wherein the first semiconductor package further includes a plurality of first bonding wires passing through the first slot to electrically connect the bonding pads to the first substrate.

21. The mounting assembly as claimed in claim 20, wherein the first semiconductor package further includes a first encapsulant formed in the first slot to encapsulate the first bonding wires.

22. The mounting assembly as claimed in claim 21, wherein the first chip has a back surface exposed from the first encapsulant.

23. The mounting assembly as claimed in claim 15, wherein the package carrier is a printed circuit board.

24. The mounting assembly as claimed in claim 15, wherein the package carrier is a second semiconductor package, further comprising a second substrate, a second chip, and a plurality of third external terminals, wherein the third external terminals are disposed on the bottom surface of the second substrate, and the first connecting pads and the second connecting pads are disposed on the top surface of the second substrate.

25. The mounting assembly as claimed in claim 24, wherein the second chip is disposed on the top surface of the second substrate without covering the first connecting pads, nor the second connecting pads, nor the compensating bumps.

26. The mounting assembly as claimed in claim 24, wherein the second semiconductor package is almost the same as the first semiconductor package, comprising a plurality of second bonding wires and a second encapsulant.

27. The mounting assembly as claimed in claim 15, wherein the first external terminals and the second external terminals include plated pillar bumps or gold stud bumps.

28. The mounting assembly as claimed in claim 15, wherein the first external terminals and the second external terminals have profiles of hemi-pyramids or hemi-cones.
